(19) United States
(12) Patent Application Publication
(10) Pub. No.: US 2004/0030535 A1
(43) Pub. Date: Feb. 12, 2004

(54) Data processing system

(76) Inventors: Ian R. Johnson, Nr Cowbridge (GB); Gethin R. Jones, Bridgend (GB)

Correspondence Address: James R Yee, Howard & Howard Attorneys, Suite 101, 1400 Woodward Avenue, Bloomfield Hills, MI, 48304-2856, US

(21) Appl. No.: 10/344,883

(22) PCT Filed: Aug. 6, 2001
(86) PCT No.: PCT/EP01/09141

(30) Foreign Application Priority Data
Aug. 14, 2000 (GB) 0019778.0

(51) Int. Cl. H03F 1/26; G06F 15/00; H04B 15/00

(52) U.S. Cl. 702/189

(57) ABSTRACT

A data processing system comprises a database located on a web site and a plurality of independent generators of raw data signals each associated with a user known to the owner of the web site and each able to be connected to the web site, such as through an internet service provider. The data signals are processed at the database, by means of an analysis engine in accordance with parameters chosen by or specific to each user or group of users, to produce processed data that are stored on a server associated with the database and which are selectively accessible to individual users on conditions prearranged with the owner of the database. The data processing system is particularly one in which the owner of some data-processing software sells licenses to firms or individuals who wish to use that software to analyse results of data-generating equipment sold to them by said owner.

This invention relates to a data processing system, and particularly one in which the owner of some data-processing software sells licences to firms or individuals who wish to use that software to analyse results of data-generating equipment sold to them by the said owner.

The invention is particularly applicable to the measurement of various analytes as indicators of organic contamination on a surface or in a liquid.

Currently products are known for measuring organic contamination by using the technique of ATP bioluminescence, in which the output is a light signal that is able to be quantified by means of a sensitive luminometer. Similar known products measure the contamination of surfaces by assessment of the presence on that surface of a protein, using a chemistry that gives a colour complex able to be measured by means of a photometer.

Self-contained test reagent delivery systems, for both of adenosine triphosphate (ATP) and protein testing, are available. These systems are used in various industries, such as food and beverage manufacture; food service and catering; cosmetics and toiletries; water treatment, and in hospitals. The technology could also be applied to many other luminescence or colorimetric analyses. In addition, other signal inputs could be used, such as for measuring temperature and humidity.

For measuring contamination on surfaces, a swab made from inert fibrous material is used to collect a sample by wiping the surface. Liquid samples may be processed by using conventional pipettes or purpose-made samplers, as part of a self-contained test device.

Software tools for viewing and presenting data are available for use in individual personal computers (PCs) or local area networks (LANs). For multi-site companies (which may also be multi-national) it may be desirable to collate information from individual sites for analysis at a single location (which may be in another country).

When the contaminant of interest does not contain living or dead cells, the eluting liquid is intended to react to the presence of protein in the swab by becoming optically dense at a rate that corresponds to the amount of contaminant present on the swab. In this case the monitor includes a photocell and a timer to detect the change of density with time. In either case, the monitor may be regarded as a source of raw data signals.

The present invention aims at providing means whereby raw data produced by users are able to be processed at a location remote from the users by an analysis engine, and made available selectively both to specific users and to firms associated with a group of users. Thus, in the case of a company making comestibles, while the swab results at the specified monitoring points throughout its food-processing system would be made available to the company on demand or routinely, the results could also be read out by process control personnel at the head office, despite its being physically remote from the company's location.

Accordingly the present invention provides a data-processing system that is as claimed in the appended claims.

The invention will now be described by way of example with reference to the accompanying drawing, in which:

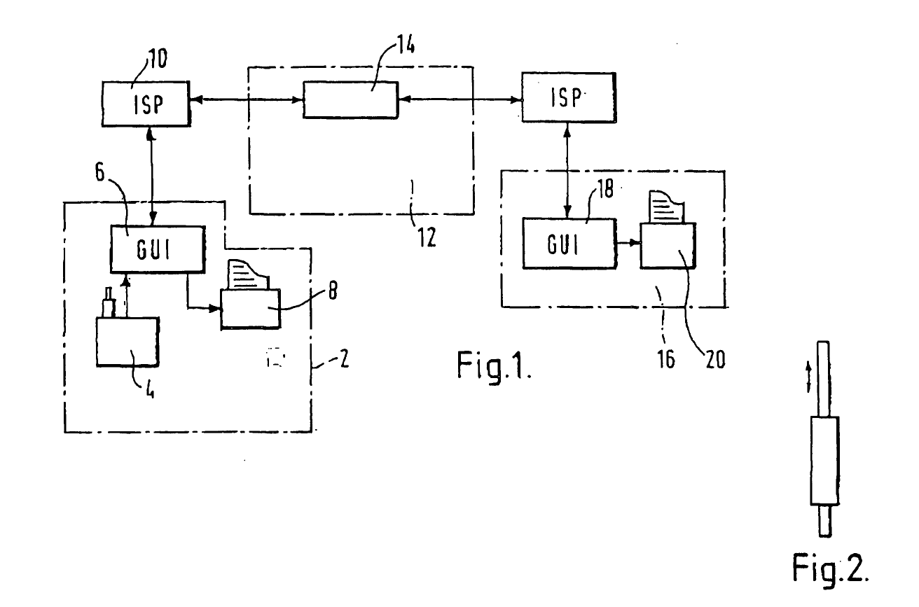

FIG. 1 is a diagrammatic view of one embodiment of the system of this invention, and

FIG. 2 is a diagrammatic side elevation of a self-contained single-use surface or liquid contamination test, with a swab or liquid sampler projecting from it.

In the drawing, a licensed user of the invention situated at a location 2 has a swab monitor 4 connected to a graphical user interface (GUI) 6 that has an output device 8 such as a stand-alone or network printer connected to it. When selling the swabs, reagents and monitors to the intended users, the firm contracted to analyse the raw data provides its customers with CD RoMs or other means containing software by which the users are able to have their GUIs connected to the same or different internet service providers (ISP) 10, and thus are provided with electronic access to the Internet (web) 12 in general, and in particular to the owner's web site 14. In addition, each monitor would have a built-in modem (not shown) by which the monitor would be able to be connected to its ISP.

While the monitor may be intended to relay to site 14 only the raw results from each swab reading, it is within the purview of this invention for each monitor to have within it means for reading from each swab holder or swab data indicating its identity (serial number), and these data would also be transmitted to the site 14 with the results data. The analysis engine at the site could be arranged to associate each set of results with particular swabs, types of tests or type of monitor. The site owner would know from the sales of its swabs, particularly if they were not reusable, the quantity of reagents that would be consumed after all the swabs had been used. Any discrepancy between the use of reagents and the number of swabs could indicate that the user had obtained access to some of the necessary reagents other than through the owner. While this information could be useful commercially, the use of unlicensed reagents from unknown sources could throw doubt on the validity of the test results.

Although not shown in FIG. 1, the owner has at its web site 14 equipment for identifying each person visiting the site and checking if it is a registered licensee. Once the identification has been made to its satisfaction, the requirements placed on the owner by each licensee are accessed and sent to an analysis engine (not shown) associated with the site, so that the raw data from the respective user (licensee) are analysed in accordance with the current contract between the owner and the user. After analysis, the results of the processing are placed in an associated server (also not shown). These results are either held for accessing on demand by the user, or for supplying by e-mail to the user.

While the analysis engine would process only one set of data from one monitor at any instant, it would be expected that there would be a series of swab data to be processed, because it would be rare for a food-processing plant to have only one point at which the hygiene would be monitored. What could be expected to happen is that the licensee would decide all the points in the or each of its ingredient-processing lines at which tests would be made. Depending on the sort of plant, and the expected source of contamination at each point, criteria would be developed about what levels of test results would be ‘acceptable’, ‘questionable’ or ‘bad’ for each point, to arrive at a test protocol for the particular line being monitored. The owner would have a library of protocols, grouped according to industries, so that new licensees could have a choice of existing protocols, knowing that each had been used in practice by other firms in the same industry.

The monitor could be arranged to identify to the owner the test point in the process at which the swab was taken. The whole batch of tests associated with one food-processing plant could be kept associated with each other by the analysis engine, and fed as a batch into the processed-results server. This would give the user access to all the results from one production line and, by classifying the results at each test point, would indicate those points in the line to which particular attention would have to be paid to ensure that any weaknesses in hygiene procedures would be strengthened. Thus the owner would have the onus of ensuring that the correct protocol was used for the results from each monitor, to keep the results from different lines at the same site separate from each other, and for supplying to each licensee the classified results for each individual line. These results would also have to be stored for indefinite periods by the owner, so that the users and their headquarters etc. would be able to compare variations with time of the results for all the lines at one plant or in one group of associated companies.

Although known monitors, using photometry to convert the luminosity or opacity of the mixed reagents into a digitised value, or operating on other types in input variables, such as temperature, humidity, conductivity, turbidity, pressure or electronic tag information, could be used in embodiments of this invention, it is within the purview of this invention to use monitors that could convert any variable analogue signal into a digital one. In addition, although the monitor has been described above as having an integral modem, it is envisaged that the monitor could take the form of a hand-held unit for enabling test data at each test point to be relayed to an ISP by means of wireless application protocol (WAP) technology.

Some foreseen users of this invention will be members of a larger group of companies, or holders of a franchise from a franchisor. In either case, the head office or franchiser may require access to the processed data, for comparison with other members of the group or other franchisees. Each such entitled customer would be located at location 16, and would have its own GUI 18 and output device 20. By means of the same or other ISP 22, the customer would have equivalent access to the web site 14. However, its access facilities would be different from those of individual users, likewise by arrangement with the site owner. While the individual users would usually be barred from accessing the data from other locations, the customers would negotiate with the owner for access to the processed data for all members of its group, or at least those in the same country.

One of the advantages of using a web site at which to process all the incoming data is that access is equally convenient to all users, wherever the users or customers are located, and at whatever time locally they require access. It is also productive to have the analysis engine, and all the test protocols, at one location. Up to now, it has been known, when the analysis of test results is done at a location remote from the sources of raw data, for the owner of the analysis engine to have to send out to all its customers (licensees) replacement CD RoMs when anything in the system changes, such as telephone access numbers. This is an inconvenient and expensive overhead expense, requiring as it does that the owner knows the exact address of each user.

The present invention has the advantage of requiring the owner to supply to each of its new licensees only the software necessary for it to have access to a convenient ISP, such as Freeserve or other ISP using 0800 or other ‘free’ access numbers. Once a user has been allocated an e-mail address, and informed the owner of it, the user can have access to its respective results from anywhere in the world, and all for the cost of a free or local call to its ISP.

It will thus be seen that this invention provides a data-processing system in which the analysis and presentation of test data are carried out at a location physically remote from all the users of process-monitoring equipment.

1 A data-processing system comprising a database located on a web site, and a plurality of independent generators of raw data signals each associated with a user known to the owner of the web site and each able to be connected to the web site, such as through an internet service provider, the data signals being processed at the database by means of an analysis engine in accordance with parameters chosen by, or specific to, each user or group of users, to produce processed data that are stored on a server associated with the database, the stored data being rendered selectively accessible to individual users on conditions prearranged with the owner of the database.

2 A system as claimed in claim 1, in which each raw data generator takes the form of a monitor adapted to generate a digitised value of a test operation of a variable analogue, and to transmit the raw data signal to the database.

3 A system as claimed in claim 2, in which the monitor uses photometry to produce a digital signal representing the luminosity or opacity of a mixture of liquid reagents into which material from a test point has been introduced.

4 A system as claimed in claim 3, in which the test material is introduced into the mixture by elution from a swab of chemically-inert material.
